(19) United States
(12) Patent Application Publication
(10) Pub. No.: US 2013/0276702 A1
(43) Pub. Date: Oct. 24, 2013

(54) GAS RECLAMATION AND ABATEMENT SYSTEM FOR HIGH VOLUME EPITAXIAL SILICON DEPOSITION SYSTEM

(71) Applicant: APPLIED MATERIALS, INC., Santa Clara, CA (US)

(72) Inventor: David K. CARLSON, San Jose, CA (US)

(21) Appl. No.: 13/868,347

(22) Filed: Apr. 23, 2013

Related U.S. Application Data
(60) Provisional application No. 61/637,477, filed on Apr. 24, 2012.

(51) Int. Cl. B01D 53/38; C23C 16/44

(52) U.S. Cl. CPC B01D 53/38; C23C 16/4412
USPC 118/723 I; 422/173; 422/169

(57) ABSTRACT

Gas reclaim and abatement are provided herein. In some embodiments, a gas reclaim and abatement system may include a chamber having walls defining an interior volume, a first body extending into the interior volume and having a channel disposed therein to provide a first gas to the chamber, wherein the first body is spaced apart from the walls to define a reaction volume between the first body and the walls, a plurality of RF coils disposed about the first body to provide RF energy to heat the first body, wherein the plurality of RF coils are disposed proximate the walls of the chamber on a side of the reaction volume opposite the first body, and a ceramic layer disposed about the first body, wherein the ceramic layer has one or more openings to provide a second gas to the reaction volume of the chamber through the ceramic layer.

### CROSS-REFERENCE TO RELATED APPLICATIONS

This application claims benefit of United States provisional patent application Ser. No. 61/637,477, filed Apr. 24, 2012, herein incorporated by reference in its entirety.

### FIELD

Embodiments of the present invention generally relate to semiconductor processing equipment, and more specifically, gas and precursor recovery equipment and techniques in high efficiency epitaxial film deposition equipment.

### BACKGROUND

For most substrate processing applications, gases and precursors are considered waste and there is a significant cost of both materials and disposal. Stand alone systems have been developed to reclaim some of the materials but these are not integrated to the system.

A big driver in cost-per-wafer for a traditional epitaxial reactor is the consumables such as silicon source gas, hydrogen, hydrogen chloride. In a traditional epitaxial reactor, the gases are reacted at <5% efficiency in the epitaxial reaction chamber, then vented out to scrubber systems to render the chemistry inert for safe disposal.

In addition, the inventor has observed that conventional abatement systems are typically configured to treat exhaust gases having different compositions coming from multiple process chambers. In order to accommodate for such a broad range of exhaust gases, the abatement systems are typically complex, expensive, and energy inefficient. Furthermore, the inventor has observed that because conventional abatement systems are utilized to treat exhaust gases from multiple process chambers simultaneously, components of the abatement system are typically located in a service area that is remote from the process chamber. As such, to facilitate transporting the exhaust from a process chamber and providing it to the abatement system over a far distance, certain components, for example such as vacuum pumps, must be more powerful, thereby further increasing the cost of the abatement system

Therefore, the inventors have provided embodiments of a substrate processing tool that may provide some or all of high process gas and/or precursor utilization, abatement, and reclamation in a low cost, and a relatively simple reactor design having high throughput and process quality.

### SUMMARY

Gas reclaim and abatement are provided herein. In some embodiments, a gas reclaim and abatement system may include a chamber having walls defining an interior volume; a first body extending into the interior volume and having a channel disposed therein to provide a first gas to the chamber, wherein the first body is spaced apart from the walls to define a reaction volume between the first body and the walls; a plurality of RF coils disposed about the first body to provide RF energy to heat the first body, wherein the plurality of RF coils are disposed proximate the walls of the chamber on a side of the reaction volume opposite the first body; and a ceramic layer disposed about the first body, wherein the ceramic layer is disposed within the chamber proximate the walls chamber on a side of the reaction volume opposite the first body, and wherein the ceramic layer has one or more openings to provide a second gas to the reaction volume of the chamber through the ceramic layer.

In some embodiments, a substrate processing tool may include a substrate processing module including an enclosure having a lower surface to support a substrate carrier, wherein the substrate processing module includes a gas injector to provide process gases to a processing volume in the processing module, the substrate carrier for supporting one or more substrates in the substrate processing module, the carrier having a first exhaust outlet, an exhaust assembly including an inlet disposed proximate the carrier to receive process exhaust gases from the first exhaust outlet of the carrier, and a foreline having a first inlet end coupled to the exhaust assembly and a second outlet end, a cooling trap coupled to the foreline between the first inlet end and the second outlet end of the foreline to reclaim process gases by removing condensable material from the first gas when flowing through the foreline, a vacuum pump having an outlet and an inlet coupled to the second outlet end of the foreline, and an abatement system, the abatement system further including a chamber having an interior volume, a first body extending into the interior volume and coupled to the outlet of the vacuum pump to provide the process exhaust gases to the chamber, a plurality of RF coils disposed about the first body to provide RF energy to heat the first body, and a ceramic layer disposed about the first body to provide a second gas to the chamber through the ceramic layer.

In some embodiments, a substrate processing tool may include a plurality of substrate processing modules including an enclosure having a lower surface to support a substrate carrier, wherein the substrate processing module includes a gas injector to provide process gases to a processing volume in the processing module, at least one abatement system coupled to each of the plurality of substrate processing module, and at least one gas reclamation cooling trap coupled to each of the plurality of substrate processing modules, wherein each of the at least one gas reclamation cooling traps coupled to a same substrate processing module provide reclaimed process gases to separate gas reprocessing modules.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts an indexed inline substrate processing tool in accordance with some embodiments of the present invention.

FIG. 2 is a cross sectional view of a module of a substrate processing tool in accordance with some embodiments of the present invention.

FIG. 3 is a module of a substrate processing tool in accordance with some embodiments of the present invention.

FIG. 4 is a schematic top view of a gas inlet in accordance with some embodiments of the present invention.

FIG. 5 is a substrate carrier for use in a substrate processing tool in accordance with some embodiments of the present invention.

FIG. 6A is a schematic end view of a substrate carrier and exhaust system for use in a substrate processing tool in accordance with some embodiments of the present invention.

FIG. 6B an indexed inline substrate processing tool with coupled abatement and reclamation system in accordance with some embodiments of the present invention.

FIG. 7 depicts a substrate processing system in accordance with some embodiments of the present invention.

FIG. 8 depicts an abatement chamber suitable for use with an abatement system in accordance with some embodiments of the present invention.

FIG. 9 depicts a gas reclamation cooling trap in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of gas reclaim and abatement systems are provided herein. In some embodiments, an inventive abatement system may be configured as a point of use abatement system, thereby advantageously requiring fewer components than a conventional abatement system. In some embodiments, such inventive abatement systems may advantageously be smaller and more efficient as compared to conventional multiple chamber and/or multiple process abatement systems. In some embodiment, the exemplary embodiments of the abatement and reclaim systems described herein may be coupled to inline indexed high volume, low cost deposition system for epitaxial silicon deposition. While not limiting in scope, the inventors believe that the inventive substrate processing system may be particularly advantageous for solar cell fabrication applications.

The inventive system may advantageously provide cost effective and simple manufacturability and an energy and cost efficient usage, as compared to conventional substrate processing tools utilized to perform multi-step substrate processes.

For example, basic design components are based on flat plates to simplify manufacturing and contain cost by using readily available materials in standard forms to keep cost down. High reliability linear lamps can be used. The specific lamps can be optimized for the specific application. The lamps may be of the type typically used in epitaxial deposition reactors. Flow fields within the system can also be optimized for each specific application to minimize waste. The design minimizes purge gas requirements and maximizes precursor utilization. Cleaning gas may be added to an exhaust system to facilitate removal of deposited material from the exhaust channels. Load and unload automation can also be separated to facilitate inline processing. Complex automation can be handled offline. Substrates are pre-loaded on carriers (susceptors) for maximum system flexibility, thereby facilitating integration to other steps. The system provides for flexibility of the system configuration. For example, multiple deposition chambers (or stations) can be incorporated for multilayer structures or higher throughput.

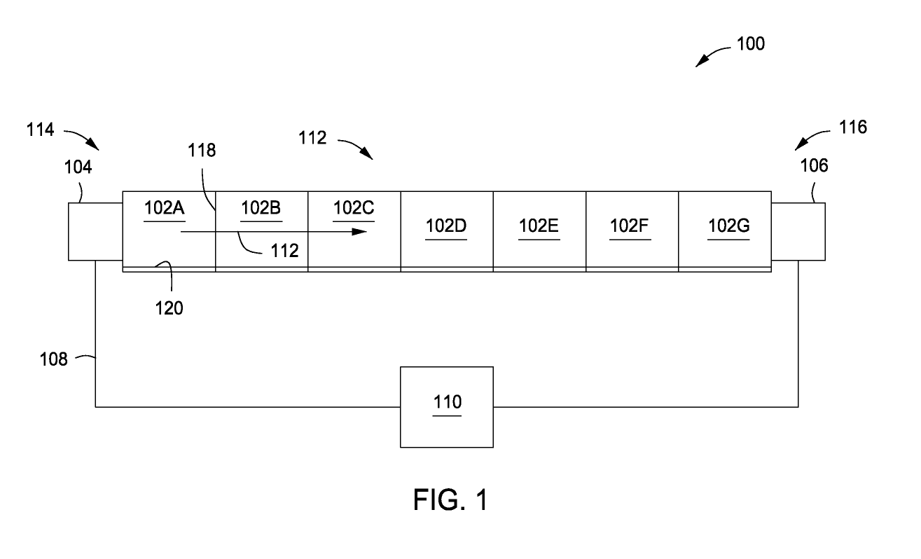

Embodiments of a high volume, low cost system for epitaxial silicon deposition may be performed using a standalone substrate processing tool, a cluster substrate processing tool or an indexed inline substrate processing tool. FIG. 1 is an indexed inline substrate processing tool 100 in accordance with some embodiments of the present invention. The indexed inline substrate processing tool 100 may generally be configured to perform any process on a substrate for a desired semiconductor application. For example, in some embodiments, the indexed inline substrate processing tool 100 may be configured to perform one or more deposition processes, for example, such as an epitaxial deposition process.

The indexed inline substrate processing tool 100 generally comprises a plurality of modules 112 (first module 102A, second module 102B, third module 102C, fourth module 102D, fifth module 102E, six module 102F, and seventh module 102G shown) coupled together in a linear arrangement. A substrate may move through the indexed inline substrate processing tool 100 as indicated by the arrow 122. In some embodiments, one or more substrates may be disposed on a substrate carrier to facilitate movement of the one or more substrates through the indexed inline substrate processing tool 100.

Each of the plurality of modules 112 may be individually configured to perform a portion of a desired process. By utilizing each of the modules to perform only a portion of a desired process, each module of the plurality of modules 112 may be specifically configured and/or optimized to operate in a most efficient manner with respect to that portion of the process, thereby making the indexed inline substrate processing tool 100 more efficient as compared to conventionally used tools utilized to perform multi-step processes.

In addition, by performing a portion of a desired process in each module, process resources (e.g., electrical power, process gases, or the like) provided to each module may be determined by the amount of the process resource required only to complete the portion of the process that the module is configured to complete, thereby further making the inventive indexed inline substrate processing tool 100 more efficient as compared to conventionally used tools utilized to perform multi-step processes.

Furthermore, separate modules advantageously allow for depositing layers of differing dopants on one or more substrates: for example, 10 microns of p++ dopants; 10 microns of p+ dopants; 10 microns of n dopants. Meanwhile, conventional single chambers prohibit deposition of different dopants since they interfere with each other. In addition, inline linear deposition where an epitaxial layer is built up in separate chambers helps to prevent over growth or bridging of the epitaxial Silicon (Si) from the substrate over the carrier due to use of a purge gas between modules (discussed below), providing an etch effect during the transfer stage from one module to the next.

In an exemplary configuration of the indexed inline substrate processing tool 100, in some embodiments, the first module 102A may be configured to provide a purge gas to, for example, remove impurities from the substrate and/or substrate carrier and/or introduce the substrate into a suitable atmosphere for deposition. The second 102B module may be configured to preheat or perform a temperature ramp to raise a temperature of the substrate to a temperature suitable for performing the deposition. The third module 102C may be configured to perform a bake to remove volatile impurities from the substrate prior to the deposition of the materials. The fourth module 102D may be configured to deposit a desired material on the substrate. The fifth module 102E may be configured to perform a post-deposition process, for example such as an annealing process. The sixth module 102F may be configured to cool the substrate. The seventh module 102G may be configured to provide a purge gas to, for example, remove process residues from the substrate and/or substrate carrier prior to removal from the indexed inline substrate processing tool 100. In embodiments where certain processes are not needed, the module configured for that portion of the process may be omitted. For example, if no anneal is needed after deposition, the module configured for annealing (e.g., the fifth module 102E in the exemplary embodiment above) may be may be omitted or may be replaced with a module configured for a different desired process.

Some embodiments of substrate processing tool 100 include an inline “pushing mechanism” (now shown) or other mechanism that is able to serially transfer the abutting substrate carriers through modules 102A-102G. For example, indexed transport can use a pneumatic plunger-type push mechanism to drive carrier modules forward through the in-line reactor.

Some or all of the plurality of modules may be isolated or shielded from adjacent modules, for example by a barrier 118, to facilitate maintaining an isolated processing volume with respect to other modules in the indexed inline substrate processing tool 100. For example, in some embodiments, the barrier 118 may be a gas curtain, such as of air or of an inert gas, provided between adjacent modules to isolate or substantially isolate the modules from each other. In some embodiments, gas curtains can be provided along all four vertical walls of each module, or of desired modules (such as deposition or doping modules), to limit unwanted cross-contamination or deposition in undesired locations of the module or carriers. Such isolation also prevents contaminants such as carbon or moisture from reaching the reaction zone/substrates.

In some embodiments, the barrier 118 may be a gate or door may that can open to allow the substrate carrier to move from one module to the next, and can be closed to isolate the module. In some embodiments, the indexed inline substrate processing tool 100 may include both gas curtains and gates, for example, using gas curtains to separate some modules and gates to separate other modules, and/or using gas curtains and gates to separate some modules. Once the push mechanism delivers the substrate carriers to a desired position in each chamber, a door/gate assembly (and chamber liner elements) forms a seal around the substrate carrier to form an enclosed region within each chamber. As the door mechanism is opening or closing a gas flow (i.e., gas purge, or gas curtain) is provided between each door and its adjacent carriers to prevent cross-contamination between chambers. The provided gas flow is received by one or more exhaust ports that are disposed in the bottom of the processing tool 100.

In some embodiments, isolation is provided by purge gas curtains using nitrogen or argon gas depending on the location of the gas curtain. For example, the gas curtain in the hotter processing regions would be formed using argon gas. The gas curtains in colder regions near the gates, away from the hotter processing regions, could by nitrogen to minimize cost of operation. The nitrogen gas curtains can only be used in cold, inert sections of each module.

In some embodiments, a load module 104 may be disposed at a first end 114 of the indexed inline substrate processing tool 100 and an unload module 106 may be disposed at a second end 116 of the indexed inline substrate processing tool 100. When present, the load module 104 and unload module 106 may facilitate providing a substrate to, and removing a substrate from, the indexed inline substrate processing tool 100, respectively. In some embodiments, the load module 104 and the unload module 106 may provide vacuum pump down and back to atmospheric pressure functions to facilitate transfer of substrates from atmospheric conditions outside of the indexed inline substrate processing tool 100 to conditions within the indexed inline substrate processing tool 100 (which may include vacuum pressures). In some embodiments, one or more substrate carrier transfer robots may be utilized to provide and remove the substrate carrier from the load module 104 and the unload module 106, thereby providing an automated loading and unloading of the substrate carrier to and from the indexed inline substrate processing tool 100.

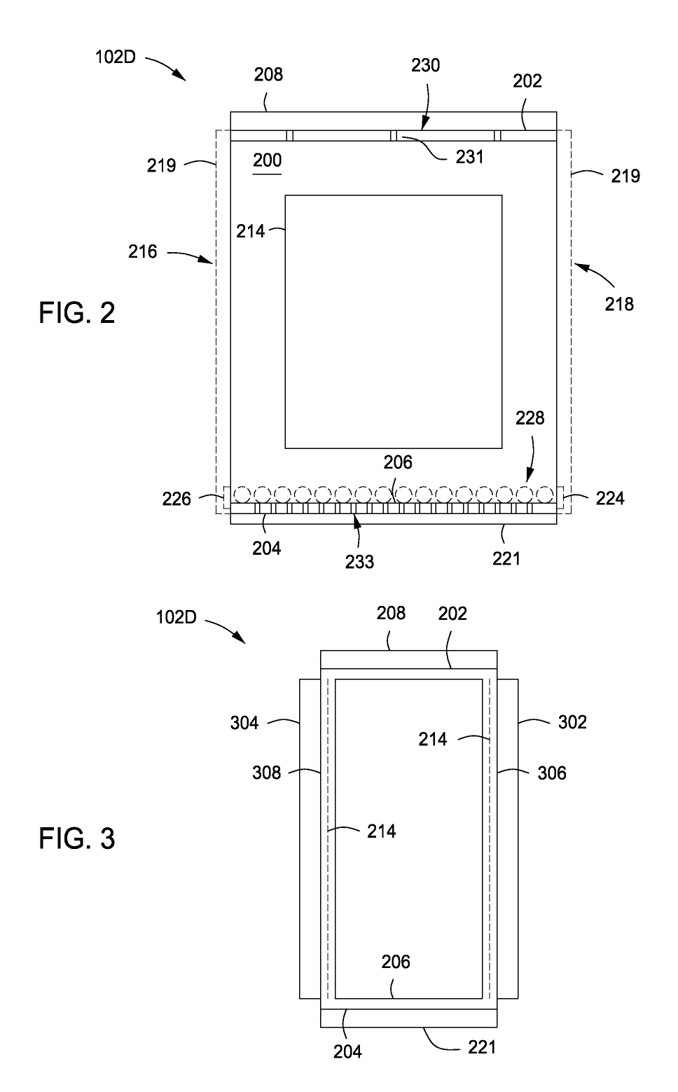

In some embodiments, a track 120 may be provided along the axial length of the indexed inline substrate processing tool 100 to facilitate guiding the substrate carrier through the indexed inline substrate processing tool 100. The track 120 may be provided along a floor of a facility or other base surface upon which the indexed inline substrate processing tool 100 is mounted. In such embodiments, each module may be configured to be assembled such that the track 120 may be positioned along an exposed bottom portion of the module to facilitate moving the substrate carrier along the track 120 and through each respective module. Alternatively, the track 120 may be mounted to a bottom surface of the modules once assembly in a linear array. Alternatively, portions of the track 120 may be mounted to a bottom surface of each individual module such that the complete track 120 is formed after assembly of all of the modules in a linear array. In some embodiments, the track 120 may include wheels, ball bearings or other types of rollers to facilitate low friction movement of the substrate carrier along the track 120. In some embodiments, the track 120 may be fabricated from or may be coated with a low friction material, such as described below with respect to FIG. 2, to facilitate low friction movement of the substrate carrier along the track 120.

In some embodiments, a cleaning module 110 may be disposed between the load module 104 and the unload module 106. When present, the cleaning module 110 may clean and/or prepare the substrate carrier to receive another one or more substrates for a subsequent run through the indexed inline substrate processing tool 100 (as indicated by the return path arrow 108). As such, the substrate carriers may be re-used multiple times.

FIG. 2 depicts a cross sectional view of an exemplary configuration of a module, such as module 102D, that may be used as one or more of the modules of the plurality of modules 112 described above, and in some embodiments, as a module configured for the deposition of materials on a substrate. Although generally discussed below in terms of a specific module (102E), the below discussion generally applies to all modules with the exception of components and/or configurations only specifically required for a deposition process.

Referring to FIG. 2, in some embodiments, the module 102D generally comprises an enclosure 202. The enclosure 202 may be fabricated from any material suitable for semiconductor processing, for example, a metal such as aluminum, stainless steel, or the like. The enclosure 202 may have any dimensions suitable to accommodate a substrate carrier (e.g., substrate carrier 502 described below) configured to carry one or more substrates of a given size as well as to facilitate a desired flow rate and profile. For example in some embodiments, the enclosure may have a height and length of about 24 inches or about 36 inches and a depth of about 6 inches.

In some embodiments, the enclosure 202 may be assembled by coupling a plurality of plates together to form the enclosure 202. Each enclosure 202 may be configured to form a particular module (e.g., module 102D) that is capable of performing a desired portion of a process. By assembling the enclosure 202 in such a manner, the enclosure 202 may be produced in multiple quantities for multiple applications via a simple and cost effective process.

A lower surface 206 of the enclosure supports the substrate carrier and provides a path for the substrate carrier to move linearly through the module 102D to an adjacent module of the plurality of modules. In some embodiments, the lower surface 206 may be configured as the track 120. In some embodiments, the lower surface 206 may have the track 120, or a portion thereof, coupled to the lower surface 206. In some embodiments, the lower surface 206, or the track 120, may comprise a coating, for example, a dry lubricant such as a nickel alloy (NiAl) containing coating, to facilitate movement of the substrate carrier through the module 102D. Alternatively, or in combination, in some embodiments, a plurality of rollers (shown in phantom at 228) may be disposed above the lower surface 206 to facilitate movement of the substrate carrier through the module 102D. In such embodiments, the plurality of rollers 228 may be fabricated from any material that is non-reactive to the process environment, for example, such as quartz (SiO₂).

In some embodiments, a barrier 219 may be disposed proximate the first end 216 and/or second end 218 of the enclosure 202 (e.g., to form the barrier 118 as shown in FIG. 1). When present, the barrier 219 isolates each module of the plurality of modules from an adjacent module to prevent cross contamination or mixing of environments between modules. In some embodiments, the barrier 219 may be a stream of gas, for example a purge gas, provided by a gas inlet (e.g., such as the gas inlet 208) disposed above the module 102D. Alternatively, or in combination, in some embodiments, the barrier 219 may be a movable gate. The gate provides additional isolation for certain processes, for example, during the deposition part of the sequence.

In some embodiments, the gate may be fabricated from a metal, such as aluminum, polished stainless steel, or the like. In other embodiments, the gates in hotter regions of the processing system can be made out of quartz to withstand the high temperatures.

In some embodiments, the module 102D may comprise one or more windows disposed in one or more sides of the enclosure, for example such, as the window 214 disposed in the side 220 of the enclosure 202, as shown in FIG. 2. When present, the window 214 allows radiant heat to be provided into the enclosure 202 from, for example, a radiant heat lamp disposed on a side of the window 214 opposite the interior of the enclosure 202. The window 214 may be fabricated from any material suitable to allow the passage of radiant heat through the window 214 while resisting degradation when exposed to the processing environment within the enclosure 202. For example, in some embodiments, the window 214 may be fabricated from quartz (SiO₂).

In some embodiments, the module 102D may include a gas inlet 208 disposed proximate a top 230 of the enclosure 202 to provide one or more gases into the enclosure 202 via through holes 231 formed in the enclosure 202. The gas inlet 208 may be configured in any manner suitable to provide a desired process gas flow to the enclosure 202. Gas injection may be provided between the two substrate carriers to contain the process gases in the reaction zone between the two substrate carriers, and/or purge gases between the substrate carriers and the module walls.

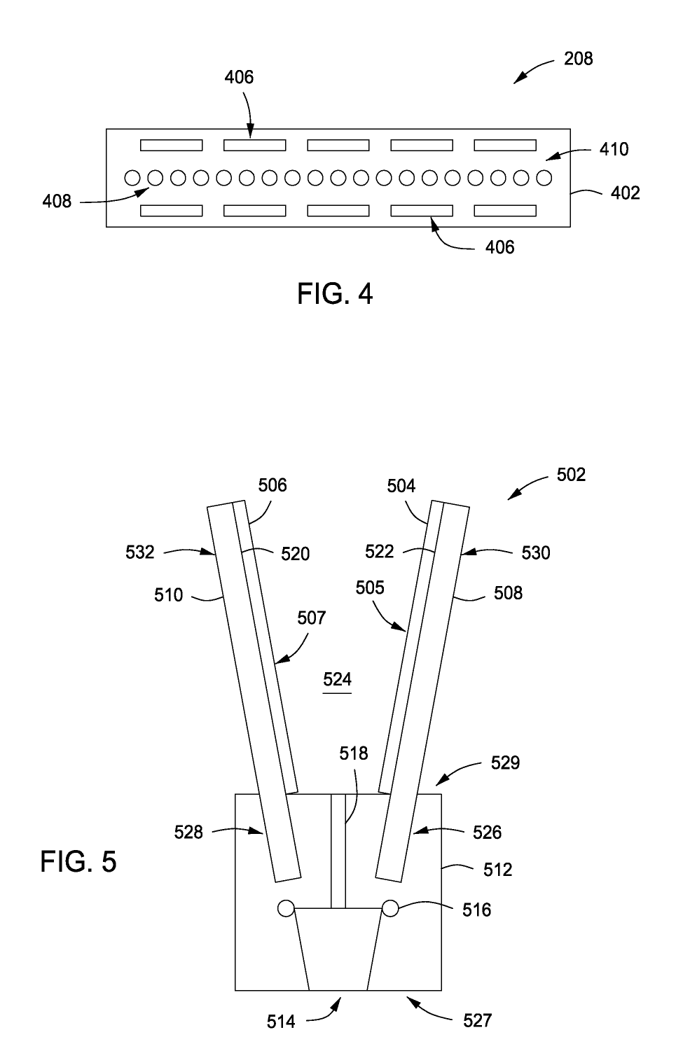

For example, referring to FIG. 4, in some embodiments, the gas inlet 208 may comprise a gas distribution plate 402 having a plurality of gas orifices 410. The gas orifices 410 may be configured to provide a desired flow of process gases into the enclosure 202. For example, in some embodiments, the gas orifices 410 may comprise a plurality of inner gas holes 408 and a plurality of outer gas slots 406, such as shown in FIGS. 4. In such embodiments, the inner gas holes 408 may provide a high velocity jet flow of process gases to a central area of the enclosure 202 to facilitate a process. In some embodiments, outer gas slots 406 may provide a lower velocity laminar flow of process gases over substrates disposed in the substrate carriers.

Referring back to FIG. 2, in some embodiments, the module 102D may comprise an exhaust 221 coupled to a portion of the enclosure 202 opposite the gas inlet 208 (e.g. the bottom 204) to facilitate the removal gases from the enclosure 202 via passageways 233 formed in the bottom 204 of the enclosure 202.

Referring to FIG. 3, in some embodiments, the module 102D may include one or more heating lamps (two heating lamps 302, 304 shown) coupled to the sides 306, 308 of the enclosure 202. The heating lamps 302, 304 provide radiant heat into to enclosure 202 via the windows 214. The heating lamps 302, 304 may be any type of heating lamp suitable to provide sufficient radiant heat into the enclosure to perform a desired portion of a process within the module 102D. For example, in some embodiments, the heating lamps 302, 304 may be linear lamps or zoned linear lamps capable of providing radiant heat at a wavelength of about 0.9 microns, or in some embodiments, about 2 microns. The wavelengths used for lamps in various modules may be selected based upon the desired application. For example, the wavelength may be selected to provide a desired filament temperature. Low wavelength bulbs are less expensive, use less power, and can be used for preheating. Longer wavelength bulbs provide high power to facilitate providing higher process temperatures, for example, for deposition processes.

In some embodiments, Infrared (IR) lamps may be provided in one or more zones to provide heat energy to the substrate carriers and ultimately to the substrates. Portions of the chamber where no deposition is desired, such as the windows, may be fabricated of materials that will not absorb IR light energy and heat up. Such thermal management keeps deposition substantially contained to desired areas. The one or more zones of IR lamps, for example in horizontal bands from top to bottom of sides of the module, facilitate controlling vertical temperature gradients to compensate for depletion effects or other vertical non-uniformities of deposition or other processing. In some embodiments, temperature can also be modulated over time as well as between zones. This type of granular temperature control, in addition to the gas injection modulation described above with respect to FIG. 4, or combinations thereof, can facilitate control of substrate processing results from top to bottom of the substrates as well as lateral edge to edge (for example, a thickness of a deposited film or uniformity of dopant concentration and/or depth).

FIG. 5 depicts at least one exemplary embodiment of a substrate carrier 502 that may be used with embodiments of the present invention described herein. The substrate carrier 502 may support two or more substrates and carry the two or more substrates through the indexed inline substrate processing tool 100 or to a cluster substrate processing tool (not shown). In some embodiments, the substrate carrier 502 may generally include a base 512 and a pair of opposing substrate supports 508, 510. One or more substrates, (substrate 504, 506 shown in FIG. 5) may be disposed on each of the substrate supports 508, 510 for processing. In some embodiments, the substrate supports 508, 510 are secured on substrate carrier 502 and may be held at an acute angle with respect to each other, with the substrates facing each other and defining a reaction zone therebetween. For example, in some embodiments the substrate supports 508, 510 are held at an angle of about between 2 degrees and 10 degrees from vertical.

The base 512 may be fabricated from any material suitable to support the substrate supports 508, 510 during processing, for example such as graphite. In some embodiments, a first slot 526 and a second slot 528 may be formed in the base 512 to allow for the substrate supports 508, 510 to be at least partially disposed within the first slot 526 and second slot 528 to retain the substrate supports 508, 510 in a desired position for processing. In some embodiments, the substrate supports 508, 510 are generally slightly angled outwardly such that the substrate supporting surfaces generally oppose each other and are arranged in a “v” shape. In some embodiments, the base 512 is fabricated from an insulating material and may be either clear or opaque quartz or a combination of clear and opaque quartz for temperature management.

A channel 514 is disposed in a bottom surface 527 of the base 512 and an opening 518 is disposed through the base 512 from a top surface 529 of the base 512 to the channel 514 to form a path for one or more gases to flow through the base 512. For example, when the substrate carrier 502 is disposed in a module, such as the module 102D described above, the opening 518 and channel 514 facilitates a flow of gas from a gas inlet (e.g., gas inlet 208 described above) to an exhaust of the module (e.g., exhaust 221 of module 102D described above). The carriage may be fabricated from quartz with the exhaust and cleaning channels machined into the quartz or a metal base disposed below the quartz. A baffle may be provided to facilitate evening out the flow through the base 512.

In some embodiments, the base 512 may include a conduit 516 disposed within the base 512 and circumscribing the channel 514. The conduit 516 may have one or more openings formed along the length of the conduit 516 to fluidly couple the conduit 516 to the channel 514 to allow a flow of gas from the conduit 516 to the channel 514. In some embodiments, while the substrate carrier 502 is disposed in a module, a cleaning gas may be provided to the conduit 516 and channel 514 to facilitate removal of deposited material from the channel 514. The cleaning gases may be provided proximate one or more exhausts to prevent deposition of process byproducts within the exhaust, thereby reducing downtime necessary for cleaning//maintenance. The cleaning gas may be any gas suitable to remove a particular material from the module. For example, in some embodiments the cleaning gas may comprise one more chlorine containing gases, such as hydrogen chloride (HCl), chlorine gas (Cl₂), or the like. Alternatively, in some embodiments, an inert gas may be provided to the conduit 516 and channel 514 to minimize deposition of material on the channel 514 by forming a barrier between the exhaust gases flowing through the channel and the surfaces of the channel.

The substrate supports 508, 510 may be fabricated from any material suitable to support a substrate 504, 506 during processing. For example, in some embodiments, the substrate supports 508, 510 may be fabricated from graphite. In such embodiments, the graphite may be coated, for example with silicon carbide (SiC), to provide resistance to degradation and/or to minimize substrate contamination.

The opposing substrate supports 508, 510 comprise respective substrate support surfaces 520, 522 that extend upwardly and outwardly from the base 512. Thus, when substrates 504, 506 are disposed on the substrate supports 508, 510, a top surface 505, 507 of each of the substrates 504, 506 face one another. Facing the substrates 504, 506 toward one another during processing advantageously creates a radiant cavity between the substrates (e.g. in the area 524 between the substrate supports 508, 510) that provides an equal and symmetrical amount of heat to both substrates 504, 506, thus promoting process uniformity between the substrates 504, 506.

In some embodiments, during processing, process gases are provided to the area 524 between the substrate supports 508, 510 while a heat source disposed proximate a back side 530, 532 of the substrate supports 508, 510 (e.g., the heating lamps 302, 304 described above) provides heat to the substrates 504, 506. Providing the process gases to the area 524 between the substrate supports 508, 510 advantageously reduces exposure of the process gases to interior components of the modules, thus reducing material deposition on cold spots within the modules (e.g., the walls of the modules, windows, or the like) as compared to conventional processing systems that provide process gases between a heat source and substrate support. In addition, the inventor has observed that by heating the substrates 504, 506 via the back side 530, 532 of the substrate supports 508, 510 any impurities within the module will deposit on the back side 530, 532 of the substrate supports 508, 510 and not the substrates 504, 506, thereby advantageously allowing for the deposition of materials having high purity and low particle count atop the substrates 504, 506.

In operation of the indexed inline substrate processing tool 100 as described in the above figures, the substrate carrier 502 having a first set of substrates disposed in the substrate carrier 502 (e.g. substrates 504, 506) is provided to a first module (e.g. first module 102A). When present, a barrier (e.g., barrier 118 or barrier 219) on the first side and/or the second side of the first module may be closed or turned on to facilitate isolating the first module. A first portion of a process (e.g., a purge step of a deposition process) may then be performed on the first set of substrates. After the first portion of the process is complete, a second substrate carrier having a second set of substrates disposed in a second substrate carrier is provided to the first module. As the second substrate carrier is provided to the first module, the second substrate carrier pushes the first carrier to the second module (e.g., the second module 102B). The first portion of the process is then performed on the second set of substrates in the first module while a second portion of the process is performed on the first set of substrates in the second module. The addition of subsequent substrate carriers repeats to provide each substrate carrier to a fixed position (i.e., within a desired module), thus providing a mechanical indexing of the substrate carriers. As the process is completed in the substrate carriers may be removed from the indexed inline substrate processing tool 100 via an unload module (e.g., unload module 106).

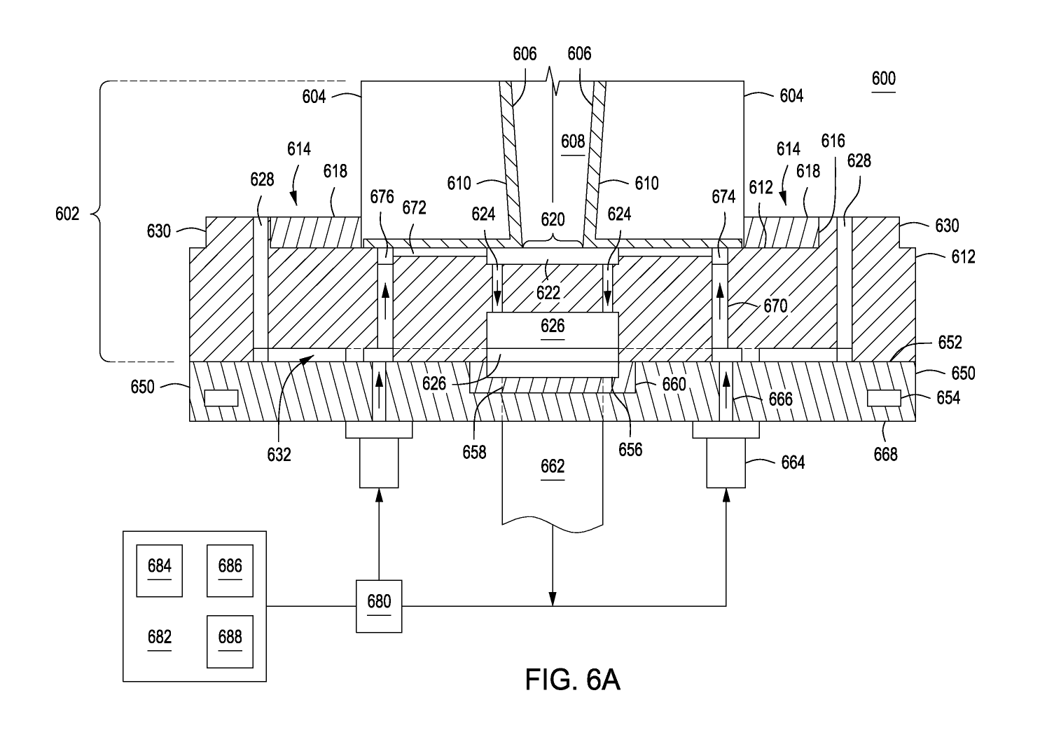

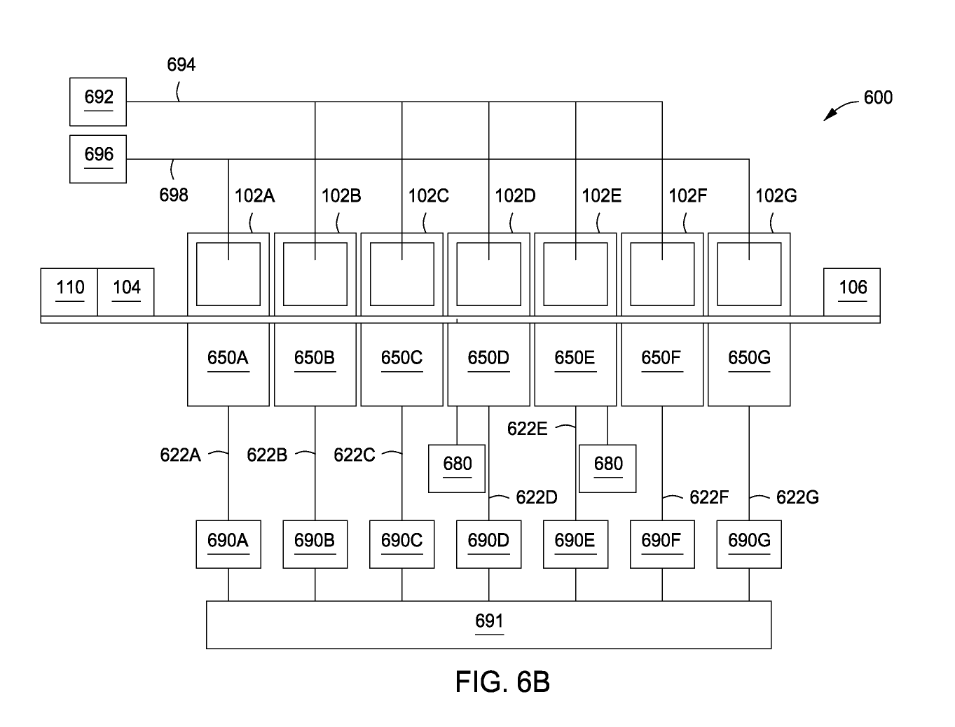

FIG. 6A depicts at least one exemplary embodiment of an exhaust system 600 that may be used with embodiments of the present invention described herein. In FIG. 6A, a movable substrate carrier 602 may be movably disposed on a base plate 650 (e.g., track 120 discussed above with respect to FIG. 1) to facilitate movement of one or more substrates through the indexed inline substrate processing tool 100 described in FIG. 1, or in and out of a standalone, inline, or cluster substrate processing tool. In some embodiments, the top surface 652 of base plate 650, may comprise a coating, for example, a dry lubricant and/or wear enhancing material such as a nickel alloy (NiAI) containing coating, or dry lubricant, to facilitate movement of the substrate carrier through, or into and out of, a processing tool. Alternatively, or in combination, in some embodiments, a plurality of rollers, wheels, low contact area bearing surfaces/features may be disposed between substrate carrier 602 and base plate 650 to facilitate movement of the substrate carrier through, or into and out of, a processing tool.

In some embodiments, the movable substrate carrier 602 may include a pair of substrate support plates 604 facing each other in a predominantly vertical orientation. The substrate support plates 604 may be coupled together (e.g., using fasteners or secured together via posts) directly, or coupled to the movable substrate carrier 602. In some embodiments, each substrate support plate 604 includes a substrate support surface 606 that extends upwardly and outwardly from a bottom portion of the substrate support plates 604, such that when the substrate support plates 604 are mounted on the movable substrate carrier 602, the substrate support surfaces 606 form a “V” pattern as shown in FIG. 6A. The substrate support surfaces 606 include one or more pockets to support one or more substrates when disposed thereon. Thus, when substrates are disposed on substrate support surfaces 606, top surfaces to be processed for each of the substrates face one another. Facing the substrates toward one another during processing advantageously creates a radiant cavity between the substrates (e.g. in the area 608 between the substrate support surfaces 606) that provides an equal and symmetrical amount of heat to substrates, thus promoting process uniformity between the substrates. In some embodiments, the substrate supports surfaces 606 are held at an angle of about between 2 degrees and 10 degrees from vertical. In some embodiments, when support plates 604 are coupled together, the sides of the support plates 604 substantially form a seal to restrain process gases from escaping from the sides of the support plates 604. In addition, when support plates 604 are placed together, a bottom exhaust slot 620 is formed along a bottom portion of the support plates 604 to facilitate the exhaust of substrate processing gases.

In some embodiments, as described with respect to the substrate carrier 502 of FIG. 5, process gases are provided to the area 608 between the substrate support surfaces 606 while a heat source disposed proximate a back side 610 of the substrate support surfaces 606 (e.g., the heating lamps 302, 304 described above) provides heat to substrates disposed on substrate support surfaces 606.

The movable substrate carrier 602 includes a transport base 612. In some embodiments, the substrate support plates 604 are disposed on a top surface 612 of a pocket 614 in transport base 612. The substrate support plates 604 may be restrained on transport base 612, for example, using fasteners or using support posts disposed on transport base 612. In some embodiments, spacers 618 may be used with substrate support plates 604 to help secure the substrate support plates 604 within an inner edge 616 of the transport base pocket 614. In some embodiments, if the substrate support plates 604 are sufficiently restrained on the transport base pocket 614, no additional fasteners may be required. In some embodiments, the spacers 618 may be fabricated from opaque quartz to block radiation and to provide insulation. In other embodiments, a clear quartz may be used to insulate without absorbing radiation.

The transport base 612 includes one or more exhaust ports and a number of exhaust channels and conduits to facilitate the exhaust of one or more different types of gases. In some embodiments, a first gas channel 622 is formed on a top surface of transport base 612 along a centerline of transport base 612 and may be fluidly coupled to the bottom exhaust slot 620 formed between substrate support plates 604. The first gas channel 622 accepts exhaust gases via bottom exhaust slot 620 from the process gases injected (e.g., via gas inlet 208) between substrate support plates 606 to process substrates when disposed thereon. The exhaust gases received via bottom exhaust slot 620 may travel along the first gas channel 622 and exit the first gas channel 622 using one or more openings 624 formed along the length of the first gas channel 622. Each of the one or more openings 624 are fluidly coupled to a second exhaust channel 626 formed on a bottom surface of transport base 612 along a centerline of transport base 612. Thus, the one or more openings 624 are fluidly the first gas channel 622 to the second gas channel 626.

In some embodiments, the transport base 612 includes one or more purge gas exhaust conduits 628 formed along the length of the transport base 612 and disposed proximate the outer edges 630 of the transport base 612 on either side of the of the substrate support plates 604. The purge gas exhaust conduits 628 receive and exhaust the purge gases injected via gas inlet 208 to form the purge gas curtain discussed above. Each of the one or more purge gas exhaust conduits 628 are fluidly coupled to a bottom pocket 632 formed on a bottom surface of transport base 612 and fluidly coupled to the second gas channel 626. Thus, the one or more purge gas exhaust conduits 628 are fluidly coupled to the second gas channel 626.

In some embodiments, the base plate 650 includes a center gas channel 656 formed on a top surface of base plate 650 along a centerline of base plate 650. The center gas channel 656 is fluidly coupled to one or more exhaust conduits 658 that extend from the top surface of base plate 650 to a bottom surface 668 of base plate 650. The center gas channel 656 fluidly couples with the second gas channel 626 on the transport base 612 to receive exhaust gases. The exhaust conduit 658 is fluidly coupled to a exhaust line 662 that receives the exhaust gases from the system 600.

In some embodiments, while the substrate carrier 602 is disposed in a process tool, a cleaning gas may be provided to the exhaust system to facilitate removal of deposited material from the exhaust system. Specifically with respect to the embodiments of FIG. 6, one or more cleaning gases may be provided by cleaning gas supply ports 664 to one or more cleaning gas supply conduits 666 formed in the base plate 650. The cleaning gases prevent deposition of process byproducts within the exhaust, thereby reducing downtime necessary for cleaning/maintenance. The cleaning gas may be any gas suitable to remove a particular material from the module or to prevent deposition on the module components. For example, in some embodiments the cleaning gas may comprise one or more chlorine containing gases, such as hydrogen chloride (HCl), chlorine gas (Cl₂), or the like. Alternatively, in some embodiments, an inert gas may be provided to the cleaning gas supply conduit 666 to minimize deposition of material in any of the gas conduits (e.g., conduits, slots, openings and channels) described above, by forming a barrier between the exhaust gases flowing through the conduits and the surfaces of the conduits.

When the substrate carrier 602 is moved into position on base plate 650, the cleaning gas supply conduits 666 substantially align with one or more cleaning gas supply conduits 670 formed in transport base 612. The cleaning gas supply conduits 670 are fluidly coupled to a cleaning gas supply channel 676 via inlets 674.

The cleaning gas supply channel 676 supplies cleaning gas to cleaning gas supply slots 672 (via) formed on a top portion of transport base 612. The cleaning gas supply slots 672 are fluidly coupled to the first gas channel on the top of transport plate 612. Thus, the cleaning gas is exhausted via the same path as the process gases as described above (e.g., via opening 624, the second gas channel 626, the center gas channel 656, exhaust conduit 658 and exhaust line 662). In some embodiments, the cleaning gas supplied by cleaning gas supply ports 664 mixes with the process gas exhaust supplied by gas inlet 208. In other embodiments, only the cleaning gas is supplied to clean the exhaust conduits described above.

In some embodiments, the center gas channel 656 may include a liner 660 fabricated from an opaque quartz material. In some embodiments the base plate 650 may include one or more cooling channels 654 to facilitate heat removal. The one or more channels may be fluidly coupled to a coolant supply (not shown).

The components of exhaust system 600 described above may be fabricated from any material suitable to support a substrate processing. For example, in some embodiments, the substrate support plates 604, or support surfaces 606, may be fabricated from graphite. In such embodiments, the graphite may be coated, for example with silicon carbide (SiC), to provide resistance to degradation and/or to minimize substrate contamination. In some embodiments, any of the components described above may be fabricated from transparent or non-transparent quartz as desired based on heating or deposition profiles required for various processes.

In some embodiments, the cleaning gas supply ports 664 may be coupled to one or more mass flow controllers 680 to provide cleaning gas to the exhaust system 600. The mass flow controllers 680 may be coupled to a controller 682 to control the amount and concentration of the one or more cleaning gases supplied. The controller 682 includes a central processing unit (CPU) 684, a memory 686, and support circuits 688. The controller 682 may be one of any form of general-purpose computer processor that can be used in an industrial setting for controlling various substrate processing tools or components thereof. The memory, or computer readable medium, 686 of the controller 682 may be one or more of readily available memory such as random access memory (RAM), read only memory (ROM), floppy disk, hard disk, optical storage media (e.g., compact disc or digital video disc), flash drive, or any other form of digital storage, local or remote. The support circuits 688 are coupled to the CPU 684 for supporting the processor in a conventional manner. These circuits include cache, power supplies, clock circuits, input/output circuitry and subsystems, and the like. Inventive methods as described herein may be stored in the memory 686 as software routine that may be executed or invoked to control the operation of the exhaust system 600 in the manner described herein. The software routine may also be stored and/or executed by a second CPU (not shown) that is remotely located from the hardware being controlled by the CPU 684.

FIG. 6B depicts a plurality of modules 102A-G each with a separate exhaust line 662 attached to abatement and reclaim systems 690A-G. Separating chambers into modules as depicted advantageously keeps each module exhaust isolated to facilitate reclaim of process gases used and exhausted via exhaust line 662. Also, separating modules keeps each module's gases more pure to facilitate reclaim of the process gases used and exhausted via exhaust line 662.

In addition, in some embodiments, like type purge gas curtains (H2 curtain in H2 chamber, N2 curtain in N2 chamber) between modules minimizes in-module mixing to make module exhaust cleaner and easier to reclaim. Furthermore, adding chlorine to deposition chamber exhaust advantageously keeps silicon species in a low reactivity gas phase rather than high reactivity solid phase, to facilitate transport and separation of silicon from hydrogen and dopant, making process exhaust much more reclaimable.

In some embodiments, the abatement and reclaim system 690A-G may be configured as a point of use abatement system, thereby advantageously requiring fewer components than a conventional abatement system. In some embodiments, such abatement and reclaim system 690A-G may advantageously be smaller and more efficient as compared to conventional multiple chamber and/or multiple process abatement systems. In some embodiments, the abatement and reclaim system 690A-G system may utilize flammable components of an exhaust gas to provide ignition of the exhaust gas to facilitate abatement of the exhaust gas, thereby operating in a more efficient manner as compared to conventional abatement systems that utilize a separate ignition fuel, for example such as a natural gas.

In some embodiments, a process gas reclamation portion of each of the plurality of abatement and reclaim systems 690A-G may be coupled to one or more gas reprocessing system 691. In some embodiments, each of the plurality of abatement and reclaim systems 690A-G may be coupled to a common gas reprocessing system 691. In other embodiments, each of the gas reclamation cooling traps 708 of the same substrate processing module (e.g, 102D) are coupled to separate reprocessing systems 691 in order to reclaim separate species of gases.

In some embodiments, one or more gas inlets 694, 698 may be coupled to gas supplies 692, 696 for providing one or more process gases into the processing volume of the each module 102A-G.

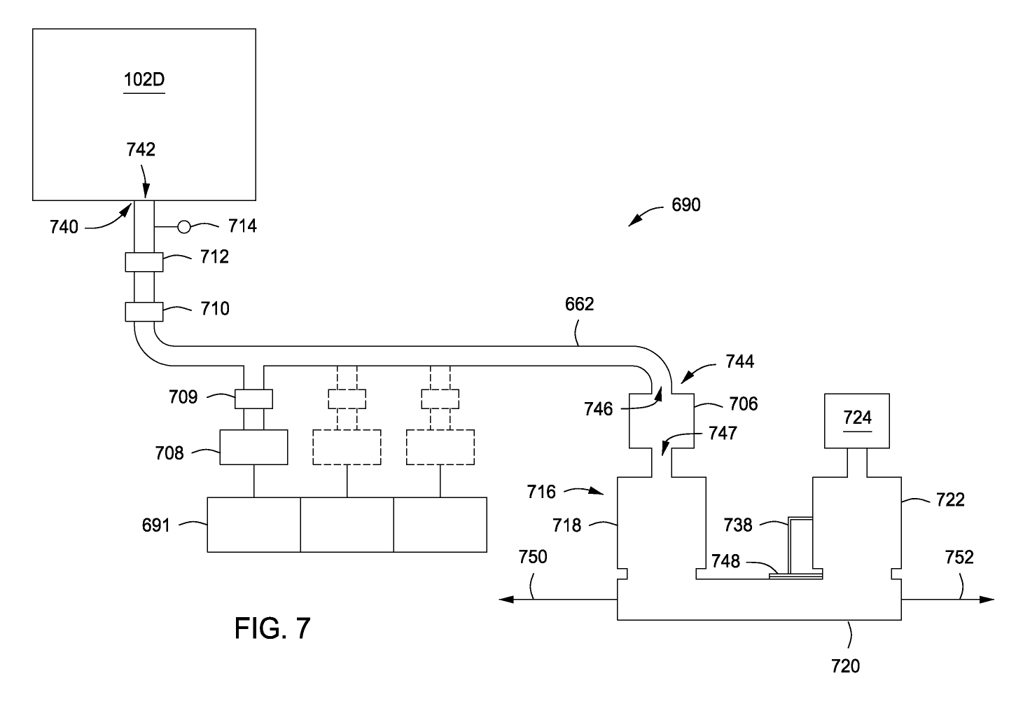

FIG. 7 depicts at least one exemplary embodiment of an abatement and reclaim system 690. The exhaust line 662 (also known as a foreline) has a first end 740 coupled to an exhaust outlet 742 of a module 102 (e.g., module 102D) and a second end 744 coupled to an inlet 746 of a vacuum pump 706. Although the exhaust outlet 742 is shown in FIG. 7 as disposed on a bottom surface of the module body, the exhaust outlet 742 may be disposed anywhere in the process module 102 suitable to facilitate efficient exhausting of the process module 102. In some embodiments, a pressure gauge 714 may be coupled to the exhaust line 662 to monitor a pressure within the exhaust line 662, for example, during operation of the process module 102 and/or abatement system 716.

The vacuum pump 706 provides a vacuum force to the exhaust line 662 to facilitate removing exhaust gases from the process module 102 and further facilitating providing the exhaust gases to the abatement system 716. The vacuum pump 706 may be any type of device that is capable of providing sub-atmospheric conditions (e.g., screw pump, gear pump, rotodynamic pump, turbo pump, inert gas Venturi systems, negative pressure house exhaust systems, or the like) suitable to facilitate the removal exhaust gases from the process module 102 and provide the exhaust gases to the abatement system 716.

In some embodiments, the exhaust line 662 may include one or more valves (two valves 710,712 shown) to facilitate control of the flow of the exhaust gases from the process module 102 to the gas reclaim cooling traps 708 and abatement system 716. For example, in some embodiments, a first valve 712, for example a throttle valve, may be coupled to the exhaust line 662 to regulate the amount of exhaust gas flowing from the process module 102 to the abatement system 716. Alternatively, or in combination, in some embodiments, a second valve 710, for example a shut off valve or a ball valve, may be coupled to the exhaust line to facilitate isolating the exhaust line 662 and/or abatement system 716 from the process module 102 to perform, for example, off line procedures such as cleaning, maintenance, replacement, or the like.

The inventor has observed that some conventional processing systems utilize one or more water cooled tubes (e.g. a water cooled exhaust line 662) to condense material as it flows through the tube. However, costly and extensive procedures are required to remove the condensed material. The inventor has also observed that some conventional processing systems may alternately, or in combination, heat portions of the tube (or exhaust line 662) to prevent condensation at certain points along the tube. However, such heating may cause failure of components of the processing system, for example such as a vacuum pump.

Accordingly, in some embodiments, a water cooled trap 708 for reclaiming process gases may be coupled to the exhaust line 662 and disposed between the process module 102 and vacuum pump 706. The inventor has observed that by providing the water cooled trap 708 condensable materials may be removed from the exhaust line 662 efficiently and without conductance loss through the exhaust line 662 as compared to condensing the material within the exhaust line 662 and subsequently removing the condensed material. In some embodiments, a valve 709 (e.g., a shut off valve, ball valve, or the like) may be disposed between the water cooled trap 708 and exhaust line 662 to facilitate removal of the water cooled trap 708 to allow removal of the condensed material. In some embodiments, a plurality of water cooled traps 708 may be provided (as shown in phantom in FIG. 7). In such embodiments, different ones of the water cooled traps 708 may be maintained at different temperatures in order to capture different species that condense at different temperatures. For example, the plurality of water cooled traps 708 may be arranged from upstream to downstream in progressively cooler temperatures such that primarily or only the desired species condenses within each cold trap 708. Providing such a configuration advantageously facilitates precursor recovery and recycling for a range of compounds. In some embodiments, process gases will be trapped out of the exhaust gas separately. For example, in some embodiments, the process materials that may be recalimed may include SiCl4, SiHCl3 and SiH2Cl2. In some embodiments, each cold trap 708 may be coupled to a gas reprocessing system reservoir 691 for collecting the trapped material for external processing. In some embodiments, the gas reprocessing system reservoir 691 can be coupled to a common distillation column for purification. In some embodiments, valve 709 allows for vacuum processing beyond this point even on an atmospheric system. In some embodiments, purge gasses (N2, H2, Ar) may be trapped and recycled separately. In some embodiments, the only “waste gas” that could not be reclaimed and would proceed to the abatement system would be the Hydrogen with dopants and residual silicon compounds.

The inventor has further observed that conventional abatement systems are typically configured to perform treatment of exhausts from multiple chambers emitting exhausts having different compositions. However, in order to accommodate such a broad range of exhaust gases, the abatement systems are complex, expensive, and energy inefficient. Moreover, the inventor has observed that because conventional abatement systems are utilized to treat exhaust gases from multiple process chambers (e.g., a facility-wide single abatement system), components of the abatement system are typically located in a service area that is remote from the process chamber. However, because such abatement systems receive exhaust from multiple process chambers, the service area accumulates hazardous process byproducts, making it unsafe for operators. In addition, a remotely located abatement system requires extended, or longer, exhaust or pumping lines (e.g., the exhaust line 662 described above). Because of the extended length, such exhaust or pumping lines suffer from varying conductance, making it difficult to efficiently and continuously pump, thereby requiring a more powerful and costly vacuum pump.

Accordingly, in some embodiments, the inventive abatement system 716 may be configured to receive and treat exhaust emitted from a single chamber or tool performing a specific process (i.e., a point of use system). The inventor has observed that by configuring the abatement system 716 in such a manner, the abatement system 716 may require less components than a conventional abatement system, thereby being smaller and more efficient as compared to conventionally utilized multiple chamber and/or multiple process abatement systems. For example, by utilizing a point of use system abatement system, the inventor has discovered that pumping line (i.e., the exhaust line 662 described above) length and size may be optimized and/or minimized for specific applications. Optimizing the length and size of the pumping line allows for a temperature and pressure within the line to be more accurately controlled, thereby minimizing deposition within the line. In addition, optimizing and/or minimizing the line length allows for a smaller and less costly vacuum pump to be used to evacuate the line and, further, minimizes the length of line with toxic and/or explosive material.

The abatement system 716 is coupled to an outlet 747 of the vacuum pump 706 and generally comprises a chamber 718, a tank 720 and a mist separator 722. The mist separator 722 may be any mist separator suitable to remove soluble gases within the water disposed within the tank. In some embodiments, water utilized within the mist separator 722 may be re-circulated back into the tank 720 and/or to components of the mist separator 722 (e.g., such as internal spray nozzles) via one or more conduits (two conduits 738, 748 shown). In some embodiments, the tank 720 may comprise one or more drain conduits (two drain conduits 750, 752 shown) to facilitate removal of contaminant containing water (e.g., arsenic or acidic contaminants) to appropriate drainage systems for treatment and/or removal. In some embodiments, waste liquid in the tank 720 may be collected and treated to reclaim materials to be reused. In some embodiments, the abatement system 716 may be coupled to an air pollution control device 724 (e.g., a facility scrubber) to remove particulates and/or gases from an exhaust stream provided by the abatement system 716.

In operation of the abatement system 716, the vacuum pump 706 evacuates a first gas from the process module 102 via the exhaust outlet 742 and through the exhaust line 662 . At least some condensable components of the first gas are trapped via the water cooled trap 708 as the first gas flows through the exhaust line 662. The first gas is then provided to the chamber 718 of the abatement system 716 via the vacuum pump 706. Flammable components of the first gas are then removed from the first gas within the chamber 718, for example as described below. Remaining soluble non-flammable components and particulates of the first gas are then treated with a water spray to capture the soluble components and particulates (e.g., via the spray chamber 818 described below), which are then collected in the tank 720. The soluble component and particulate containing water then flow towards the mist separator 722, which then removes any soluble gases within the water and exhausts the gases to a facility air pollution control device 724 (e.g., a scrubber).

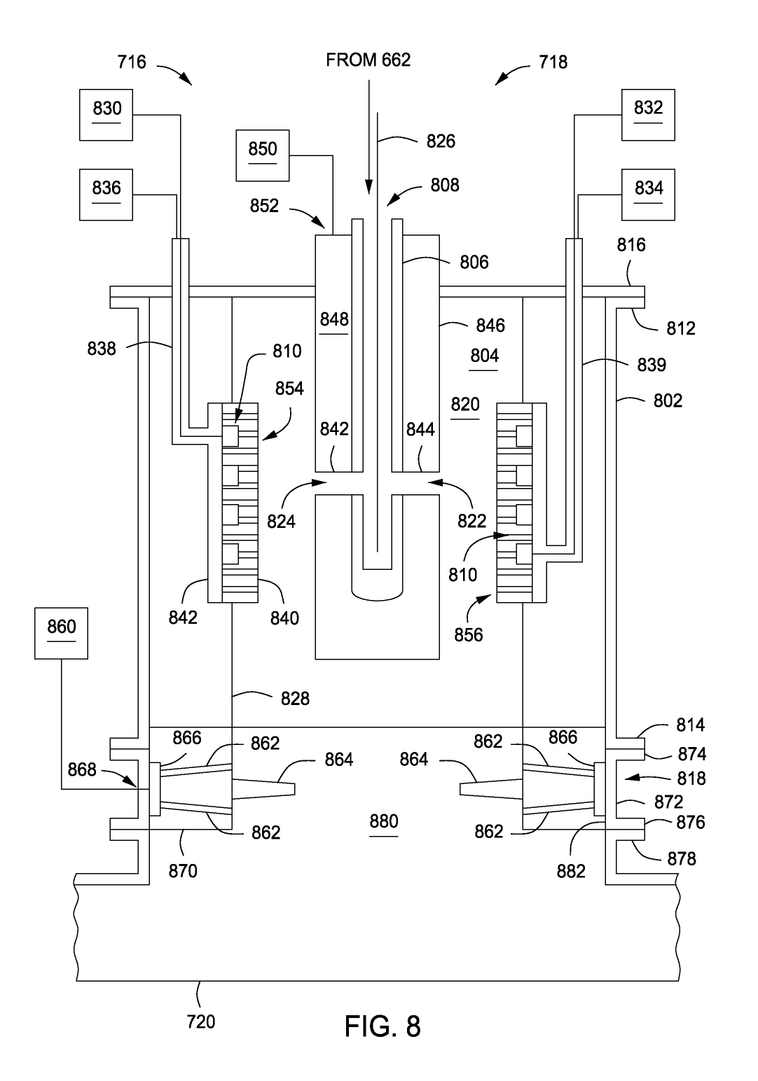

Referring to FIG. 8, the chamber 718 generally comprises walls 802 defining an interior volume 804, a first body 806 extending into the interior volume 804 and a plurality of RF coils 810 disposed about the first body 806.

The walls 802 may be fabricated from any rigid material suitable to protect the inner components (e.g., the first body 806, plurality of RF coils 810, or the like) of the chamber 718. For example, in some embodiments, the walls 802 may be fabricated from a metal such as stainless steel, aluminum, or the like. In some embodiments, one or more flanges (top flange 812 and bottom flange 814 shown) may be provided to facilitate coupling the chamber 718 to one or more additional components of the abatement system 716. For example, in some embodiments, the top flange 812 may be configured to couple a lid 816 atop the chamber 718. Alternatively, or in combination, in some embodiments, the bottom flange 814 may be configured to couple the chamber 718 to a spray chamber 818.

In some embodiments, the chamber 718 may include a liner 828 disposed on or adjacent to an inner surface of the walls 802. The liner 828 may be fabricated from any material suitable to resist degradation during use of the chamber 718. For example, in some embodiments, the liner 828 may be fabricated from quartz (SiO₂), for example, such as opaque quartz.

The first body 806 is spaced apart from the walls 802 to define a reaction volume 820 between the first body 806 and the walls 802. In some embodiments, the first body 806 include a channel 808 to provide a first gas (e.g., exhaust gas from the process module 702 described above) to the chamber 718. The channel 808 receives the first gas from the exhaust line 662 and provides the first gas to the reaction volume 820 via one or more holes (two holes 822, 824 shown) in the first body 806. In some embodiments, a temperature sensing probe or a thermocouple 826 may be disposed within the channel to allow for the monitoring of the temperature within the channel 808.

The first body 806 may be fabricated from any material that is non-reactive with the first gas, for example such as graphite. In some embodiments, the first body 806 may have a coating to prevent degradation of the first body 806 due to the exhaust gas and/or temperature within the chamber 718. For example, in embodiments where the first body 806 is fabricated from graphite, the graphite may be coated with silicon carbide (SiC). Fabricating the first body 806 from graphite or silicon carbide coated graphite facilitates coupling of RF energy to the first body 806 create heat, as discussed below.

The RF coils 810 are disposed about the first body 806 to provide RF energy to heat the first body 806. In some embodiments, the RF coils 810 are disposed proximate the walls 802 of the chamber 718 opposite the first body 806, as shown in FIG. 8. An RF power source 830 provides RF energy to the RF coils 810. An RF ground connection 832 may be coupled to the RF coils 810 to provide a return path for the RF energy. In some embodiments, one or more conduits (two conduits 838, 839 shown) may be disposed within the liner 828 and extending out of the chamber 718 to facilitate coupling the RF power source 830 and the RF ground connection 832 to the RF coils 810.

In some embodiments, the RF coils 810 may be disposed within a ceramic layer 840. The ceramic layer may be fabricated from any suitable ceramic, for example such as silicon carbide (SiC), alumina (Al₂O₃), or the like. In some embodiments, the ceramic layer 840 may include one or more openings 854, 856 to facilitate delivery of a second gas to the reaction volume 820 of the chamber 718 through the ceramic layer 840. The one or more openings 854, 856 may be holes drilled or otherwise formed through the ceramic layer 840. Alternatively or in combination, the ceramic layer 840 may be porous and the one or more openings 854, 856 may be passageways formed through the porous ceramic layer 840. In some embodiments, the second gas may be provided to the ceramic layer 840 from one or more gas supplies (two gas supplies shown 834, 836). In such embodiments, the one or more gas supplies 834, 836 may provide the second gas to a conduit 842 fluidly coupled to the ceramic layer 840 via one or more of the conduits 838, 839.

The second gas may be any type of gas capable of oxidizing the first gas. For example, in some embodiments, the second gas may be an oxygen containing gas such as oxygen (O₂), water vapor (H₂O), air that has been filtered and/or dehumidified to remove particulates and moisture (e.g., “clean dry air (CDA)”), or the like. Alternatively or in combination, in some embodiments, the second gas may be a second reactive gas such as Cl₂, HCl, HBr, or the like. Providing the second reactive gas as the second gas facilitates a more complete reduction of the effluent to water soluble materials. Each of the one or more gas supplies 834, 836 may provide the same, or in some embodiments, a different gas. For example, in some embodiments, a first gas supply of the one or more gas supplies (e.g., gas supply 834) may provide an oxidizing gas and a second gas supply (e.g., gas supply 836) may provide the second reactive gas or CDA. In some embodiments, CDA may be provided at sufficient flow rates to facilitate cooling the RF coils as well as protecting the RF coils from contact with the other gases. For example, in some embodiments, the gas supply 834 may provide one or more of the oxidizing gas and the second reactive gas while the gas supply 836 may provide CDA.

In some embodiments, a second body 846 may be disposed about the first body 806. In such embodiments, the second body 846 may be spaced apart from first body 806 to define a second interior volume 848 in the region between the second body 846 and first body 806. The second body 846 may be fabricated from any material suitable to resist degradation and protect the first body 806 during use of the chamber 718. For example, in some embodiments, the second body 846 may be fabricated from quartz (SiO₂), for example, such as opaque quartz (SiO₂).

In some embodiments, a gas supply 850 may provide a third gas, for example an inert gas (e.g., nitrogen (N), Helium (He), argon (Ar), or the like) to the second interior volume 848 via an inlet 852. When present, the second body 846 and the inert gas filled second interior volume 848 functions to protect the first body 806 from the environment within the reaction volume 820, thereby prolonging the useful life of the first body 806. In some embodiments, a plurality of conduits (two conduits 842, 844 shown) may be disposed in the second interior volume 848 to fluidly couple the channel 808 to the reaction volume 820. When present, the plurality of conduits 842, 844 isolate the second interior volume 848 from the reaction volume 820 and from the first gas.

In some embodiments, the spray chamber 818 may be disposed beneath the chamber 718 and may function to remove particulates and water soluble components from the first gas (exhaust gas) following ignition of the first gas (as described below) and prior to reaching the tank 720. The spray chamber 818 generally comprises walls 872 defining an inner volume 880 and one or more water inlets (one inlet 868 shown) to provide water (H₂O) to the inner volume 880 from a water supply 860. In some embodiments, the spray chamber may comprise two or more flanges (top flange 874 and bottom flange 876 shown) to facilitate coupling the spray chamber 818 to one or more additional components of the abatement system 716. For example, in some embodiments, the top flange 874 may be configured to couple the spray chamber 818 to the chamber 718 (e.g., via bottom flange 814 of chamber 788). In some embodiments, the bottom flange 814 may be configured to couple the spray chamber 818 to the tank 720 (e.g., via tank flange 878). Although shown as a separate component of the, the spray chamber 818 may be integrally formed with the chamber 718, thereby providing a single unit.

In some embodiments, a liner 870, for example similar to the liner 828 described above, may be disposed on an inner surface 882 of the walls 872. In such embodiments, one or more channels (four channels 862 shown) may be formed in the liner 828 and fluidly coupled to a plenum 866 to facilitate the delivery of the water (H₂O) to the inner volume 880. In some embodiments, an inwardly facing protrusion, or baffle 864 may be disposed within the spray chamber 818. The baffle 864 may provide a surface for water and particulate to adhere to, thereby enhancing the removal of particulate from the gas stream. In some embodiments, the baffle 864 may be positioned with respect to the channels 862 such that the water sprays onto the baffle 864 to wash any accumulated particulates into the tank 720.

In operation of the chamber 718 described above, the first gas is provided to the channel 808 of the first body 806 from the exhaust line 662 . In some embodiments, the first gas may be an exhaust gas produced during processing and exhausted from a process chamber (e.g., process module 702 described above) via a vacuum pump (e.g., vacuum pump 706 described above).

The first body 806 is heated via the RF coils 810 to a temperature above an ignition temperature of the flammable components of the first gas. For example, in some embodiments, the exhaust gas may comprise a hydrogen (H₂) gas. In such embodiments, the first body 806 may be heated above about 700 degrees Celsius. The temperature within the first body 806 may be monitored by the thermocouple 826. The inventor has observed that by utilizing the flammable components of the first gas to facilitate ignition, the abatement system operates in a more efficient manner as compared to conventional abatement systems that utilize a separate ignition fuel, for example such as a natural gas.

The first gas flows from the channel 808 to the reaction volume 820 via the conduits 842, 844. The second gas (e.g., an oxidizing gas) is provided to the reaction volume 820 via the ceramic layer 840 and reacts with, e.g., oxidizes, the first gas within the reaction volume 820, causing the first gas to ignite. Ignition of the first gas consumes the flammable components, leaving only the non-flammable components of the first gas. The remaining components of the first gas then enter the spray chamber 818, where remaining soluble non-flammable components and particulates of the first gas are treated with a water spray to capture the soluble components and particulates which are then collected in the tank 720.

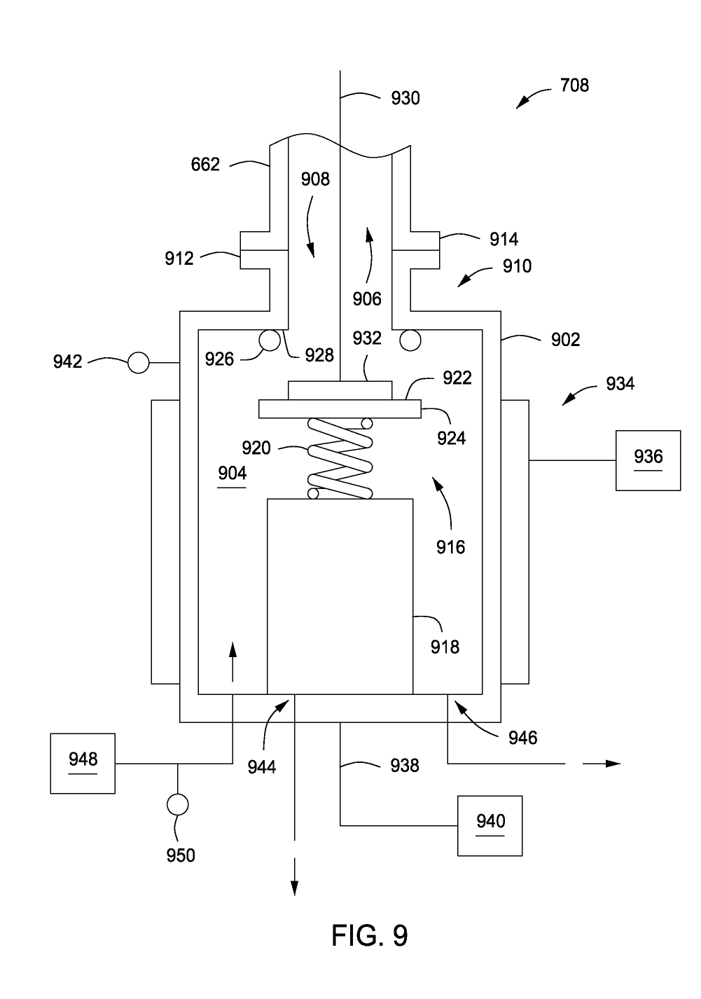

Referring to FIG. 9, the water cooled trap 708 generally comprises a housing 902 defining an inner volume 904. In some embodiments, the housing 902 comprises an upper portion 910 configured to allow the water cooled trap 708 to be removably coupled to the exhaust line 662. In such embodiments, the upper portion 910 of the housing 902 may include a flange 912 configured to mate with a flange 914 disposed on the exhaust line 662 to align a first opening 906 of the exhaust line 662 with a second opening 908 of the water cooled trap 708. In some embodiments, a pressure gauge 942 may be coupled to the housing 902 to allow for the monitoring of pressure within the water cooled trap 708.

In some embodiments, the water cooled trap 708 may include a valve 916 configured to seal the water cooled trap 708 when removed from the exhaust line 662. In some embodiments, the valve 916 may comprise a base 918, a spring 920 disposed on the base 918 and a flat member 924 disposed atop the spring 920. In some embodiments, the flat member 924 has a top surface 922 that interfaces with an inner surface 928 of the housing 902 to seal the water cooled trap 708. In some embodiments, an o-ring 926 may be disposed between the inner surface 928 of the housing 902 and the top surface 922 of the flat member 924 to facilitate the seal. In some embodiments, a plunger 930 may be disposed within the first opening 906 of the exhaust line 662. In operation, when the water cooled trap 708 is coupled to the exhaust line 662, an end 932 of the plunger 930 interfaces with the flat member 924 and compresses the spring 920, thereby opening the second opening 908 of the water cooled trap 708 and fluidly coupling the first opening 906 of the exhaust line 662 with the second opening 908 of the water cooled trap 708. When the water cooled trap 708 is removed from the exhaust line 662, the spring 920 decompresses, pushing the flat member 924 upwards to interface with the inner surface 928 of the housing 902, thereby sealing the water cooled trap 708.

A water supply 940 provides water to the inner volume 904 of the water cooled trap 708 via a conduit 938. In some embodiments, the water maybe drained via an outlet 944 in the housing 902, thereby allowing for water to be continuously circulated through the water cooled trap 708 to facilitate maintaining the water cooled trap below a desired temperature.

In some embodiments, a heater 934 may be disposed about the housing 902 to heat the water cooled trap 708 to a desired temperature to facilitate draining and/or removing condensable material from the water cooled trap 708. In such embodiments, a power source 936 may be coupled to the heater 934 to facilitate operating the heater 934. In some embodiments, the condensable material may be removed from the water cooled trap via an outlet 946 in the housing 902. In some embodiments, a gas supply 948 may be coupled to the water cooled trap 708 to provide a purge gas (e.g., an inert gas such as argon (Ar), helium (He), or the like) to facilitate purging and/or removing contaminants from the water cooled trap 708. Optionally, a pressure gauge 950 may be provided to monitor the pressure within the water cooled trap 708, for example, to prevent over-pressurizing the water cooled trap 708.

Thus, embodiments of abatement systems have been provided herein. In some embodiments, the inventive abatement system may be configured as a point of use abatement system, thereby advantageously requiring fewer components than a conventional abatement system, thus being smaller and more efficient as compared to conventionally utilized multiple chamber and/or multiple process abatement systems. In some embodiments, the inventive abatement system may utilize flammable components of an exhaust gas to provide ignition of the exhaust gas to facilitate abatement of the exhaust gas, thereby operating in a more efficient manner as compared to conventional abatement systems that utilize a separate ignition fuel, for example such as a natural gas.

While the foregoing is directed to embodiments of the present invention, other and further embodiments of the invention may be devised without departing from the basic scope thereof.

1. A gas reclaim and abatement system, comprising:
a chamber having walls defining an interior volume;
a first body extending into the interior volume and having a channel disposed therein to provide a first gas to the chamber, wherein the first body is spaced apart from the walls to define a reaction volume between the first body and the walls;
a plurality of RF coils disposed about the first body to provide RF energy to heat the first body, wherein the plurality of RF coils are disposed proximate the walls of the chamber on a side of the reaction volume opposite the first body; and
a ceramic layer disposed about the first body, wherein the ceramic layer is disposed within the chamber proximate the chamber walls on a side of the reaction volume opposite the first body, and wherein the ceramic layer has one or more openings to provide a second gas to the reaction volume of the chamber through the ceramic layer.

2. The gas reclaim and abatement system of claim 1, wherein the plurality of RF coils are disposed in the interior volume and covered by the ceramic layer.

3. The gas reclaim and abatement system of claim 1, wherein the one or more openings of the ceramic layer comprise a plurality of pores such that the second gas can be provided to the chamber through the plurality of pores.

4. The gas reclaim and abatement system of claim 1, further comprising:
a second body disposed about and spaced apart from the first body to define a second interior volume between the second body and the first body, wherein the reaction volume is disposed between the second body and the walls of the chamber.

5. The gas reclaim and abatement system of claim 4, wherein the first body comprises silicon carbide coated graphite and the second body comprises opaque quartz.

6. The gas reclaim and abatement system of claim 4, further comprising:
a first inlet to provide a third gas to the second interior volume.

7. The gas reclaim and abatement system of claim 4, further comprising:
a plurality of conduits disposed in the second interior volume and coupled to the first and second bodies to conduct the first gas from the first body to the reaction volume, wherein the plurality of conduits isolate the first gas from the second interior volume.

8. The gas reclaim and abatement system of claim 4, further comprising:
a plurality of water inlets disposed below the reaction volume to provide water (H₂O) to capture reaction products formed from a reaction of the first and second gases in the reaction volume.

9. The gas reclaim and abatement system of claim 1, further comprising:
a foreline to provide the first gas from a substrate processing system to the chamber, the foreline having a first end coupled to an exhaust outlet of a substrate processing system and a second end coupled to the chamber.

10. The gas reclaim and abatement system of claim 9, further comprising:
a cooling trap coupled to the foreline between the first end and the second end of the foreline to reclaim process gases by removing condensable material from the first gas when flowing through the foreline.

11. A substrate processing tool, comprising:
a substrate processing module including an enclosure having a lower surface to support a substrate carrier, wherein the substrate processing module includes a gas injector to provide process gases to a processing volume in the processing module;
the substrate carrier for supporting one or more substrates in the substrate processing module, the carrier having a first exhaust outlet;
an exhaust assembly including an inlet disposed proximate the carrier to receive process exhaust gases from the first exhaust outlet of the carrier; and
a foreline having a first inlet end coupled to the exhaust assembly and a second outlet end;
a cooling trap coupled to the foreline between the first inlet end and the second outlet end of the foreline to reclaim process gases by removing condensable material from the process exhaust gases when flowing through the foreline;
a vacuum pump having an outlet and an inlet coupled to the second outlet end of the foreline; and
an abatement system, the abatement system further comprising:
a chamber having an interior volume;
a first body extending into the interior volume and coupled to the outlet of the vacuum pump to provide the process exhaust gases to the chamber;
a plurality of RF coils disposed about the first body to provide RF energy to heat the first body; and
a ceramic layer disposed about the first body to provide a second gas to the chamber through the ceramic layer.

12. The substrate processing tool of claim 11, wherein the plurality of RF coils are disposed in the interior volume and covered by the ceramic layer.

13. The substrate processing tool of claim 11, wherein the ceramic layer further comprises a plurality of pores, wherein the second gas is provided to the chamber through the plurality of pores.

14. The substrate processing tool of claim 11, wherein the abatement system further comprises:
a second body disposed about the first body, wherein the plurality of RF coils are disposed about the second body.

15. The substrate processing tool of claim 14, wherein the interior volume further comprises:
a first interior volume disposed between the first and second bodies; and
a second interior volume disposed between the second body and a wall of the chamber.

16. The substrate processing tool of claim 15, wherein the abatement system further comprises:
a plurality of conduits disposed in the first interior volume and coupled to the first and second bodies to conduct the process exhaust gases from the first body to the second interior volume, wherein the plurality of conduits isolate the process exhaust gases from the first interior volume.

17. The substrate processing tool of claim 15, wherein the abatement system further comprises:
a plurality of second inlets disposed below the first and second interior volumes to provide water (H₂O) to capture reaction products formed from a reaction of the first and second gases.

18. The substrate processing tool of claim 15, wherein the cooling trap includes a plurality of cooling traps, and wherein each of the plurality of cooling traps provide reclaimed process gases to separate gas reprocessing modules.

19. A substrate processing tool, comprising:
a plurality of substrate processing modules including an enclosure having a lower surface to support a substrate carrier, wherein the substrate processing module includes a gas injector to provide process gases to a processing volume in the processing module;
at least one abatement system coupled to each of the plurality of substrate processing module; and
at least one gas reclamation cooling trap coupled to each of the plurality of substrate processing modules, wherein each of the at least one gas reclamation cooling traps coupled to a same substrate processing module provide reclaimed process gases to separate gas reprocessing modules.

20. The substrate processing tool of claim 19, wherein at least some of the at least one gas reclamation cooling traps coupled to different substrate processing modules provide reclaimed process gases to separate gas reprocessing modules.
